(19) United States
(12) Patent Application Publication
(10) Pub. No.: US 2026/0363014 A1
(43) Pub. Date: Nov. 12, 2026

(54) Vacuum Batch Heating Chamber And Methods Of Use

(71) Applicant: Applied Materials, Inc., Santa Clara, CA (US)

(72) Inventors: Sarath BABU, Singapore (SG); Palaniappan CHIDAMBARAM, Singapore (SG); Yuichi WADA, Chiba (JP); Richard HAZLEHURST, Singapore (SG); Clinton GOH, Singapore (SG); Sandeep MUNDUR DASEGOWDA, Bangalore (IN); Prashant AGARWAL, Singapore (SG); Preetham RAO, Sunnyvale, CA (US); Devi Raghavee VEERAPPAN, Eindhoven (NL); Yaoying ZHONG, Singapore (SG); Yoke Mun GOH, Singapore (SG); Siew Kit HOI, Singapore (SG); Jay Min SOH, Singapore (SG); Li Ying CHOO, Singapore (SG); Haomin XU, Singapore (SG); Xiao TAN, Singapore (SG)

(21) Appl. No.: 19/204,392

(22) Filed: May 9, 2025

(51) Int. Cl. H10P 72/00; H10P 14/20; H10P 72/10; H10P 72/76

(52) U.S. Cl. CPC H10P 72/0432; H10P 14/3434; H10P 14/38; H10P 72/1911; H10P 72/1921; H10P 72/7612; H10P 72/7616

(57) ABSTRACT

Embodiments of batch heating chambers and methods of use thereof are provided herein. In some embodiments, a batch heating chamber includes: a plurality of batch heating cassettes that are vertically stacked, wherein each batch heating cassette comprises: a plurality of walls partially defining a processing volume; one or more heating elements coupled to one or more of the plurality of walls; a plurality of support plates coupled to at least one of the plurality of walls, wherein the plurality of support plates are configured to horizontally support a plurality of substrates in a vertically stacked and spaced arrangement; and a plurality of support pins disposed on each of the plurality of support plates, wherein the support pins are configured to elevate the plurality of substrates above respective ones of the plurality of support plates.

### FIELD

Embodiments of the present disclosure generally relate to substrate processing, and more specifically, batch substrate processing.

### BACKGROUND

Substrate heating chambers are used to heat semiconductor wafers or substrates to specific temperatures to perform processes such as annealing or degassing. For example, degas chambers are specialized devices designed to remove volatile compounds and impurities from substrates by employing a vacuum or heat-based process, known as degassing. Such chambers create a controlled environment where heat or reduced pressure causes the unwanted gases or contaminants to evaporate or escape from the material's surface. Degas chambers are used to ensure the purity and performance of substrates. The process can also facilitate removing moisture, trapped gases, or solvents that could affect the quality or integrity of a final product.

However, for thick multi-layer substrates, for example, substrates used for packaging applications, a degassing process may take a long time to complete (e.g., greater than one hour). As such, a batch heating chamber may advantageously perform a degas process for a plurality of substrate, improving substrate processing throughput. A batch heating chamber may also advantageously anneal a plurality of substrates instead of a single substrate to increase processing throughput. Accordingly, the inventors have provided herein embodiments of a batch heating chamber for use with degassing or annealing applications.

### SUMMARY

Embodiments of batch heating chambers and methods of use thereof are provided herein. In some embodiments, a batch heating chamber includes: a plurality of batch heating cassettes that are vertically stacked, wherein each batch heating cassette comprises: a plurality of walls partially defining a processing volume; one or more heating elements coupled to one or more of the plurality of walls; a plurality of support plates coupled to at least one of the plurality of walls, wherein the plurality of support plates are configured to horizontally support a plurality of substrates in a vertically stacked and spaced arrangement; and a plurality of support pins disposed on each of the plurality of support plates, wherein the support pins are configured to elevate the plurality of substrates above respective ones of the plurality of support plates.

In some embodiments, a batch heating chamber includes: a chamber housing defining an interior volume therein; a plurality of batch heating cassettes that are vertically stacked within the interior volume, wherein each batch heating cassette comprises: a back wall having one or more heating elements configured to heat the batch heating cassette; sidewalls extending from the back wall having one or more heating elements configured to heat the batch heating cassette; a plurality of support plates coupled to the sidewalls, wherein the support plates are configured to hold a plurality of substrates in a vertically stacked arrangement; and a plurality of support pins disposed on each of the plurality of support plates, wherein the support pins are configured to elevate the plurality of substrates above respective ones of the plurality of support plates; and a pump port configured to be coupled to a pump.

In some embodiments, a method of processing a substrate includes: loading a plurality of substrates into a factory interface of a multi-chamber processing tool having a plurality of process chambers comprising at least one deposition chamber and at least one batch heating chamber; serially performing one or more deposition processes on the plurality of substrates via the at least one deposition chamber; and serially transferring the plurality of substrates to the at least one batch heating chamber to perform a batch heating process comprising at least one of a batch degas process or batch anneal process, wherein the at least one batch heating chamber comprises a plurality of batch heating cassettes that are vertically stacked.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic top-view of a multi-chamber processing tool in accordance with at least some embodiments of the present disclosure.

FIG. 2 depicts a schematic side view of a batch heating chamber in accordance with at least some embodiments of the present disclosure.

FIG. 3 depicts a schematic isometric view of a batch heating chamber having an actuator assembly in accordance with at least some embodiments of the present disclosure.

FIG. 4 depicts a schematic isometric view of a plurality of batch heating cassettes that are vertically stacked in accordance with at least some embodiments of the present disclosure.

FIG. 5 depicts an isometric view of a batch heating cassette in accordance with at least some embodiments of the present disclosure.

FIG. 6 depicts a cross-sectional side view of a portion of a batch heating cassette in accordance with at least some embodiments of the present disclosure.

FIG. 7 depicts a flow chart of a method of processing a substrate in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of batch heating chambers and methods of using batch heating chambers for processing a substrate are provided herein. Batch heating of substrates may advantageously improve process throughout, especially for processes that require longer heating times. The batch heating chambers provided herein include a plurality of batch heating cassettes that hold multiple substrates. The plurality of batch heating cassettes may be independently controlled to advantageously improve temperature uniformity of processing volumes of the batch heating chambers.

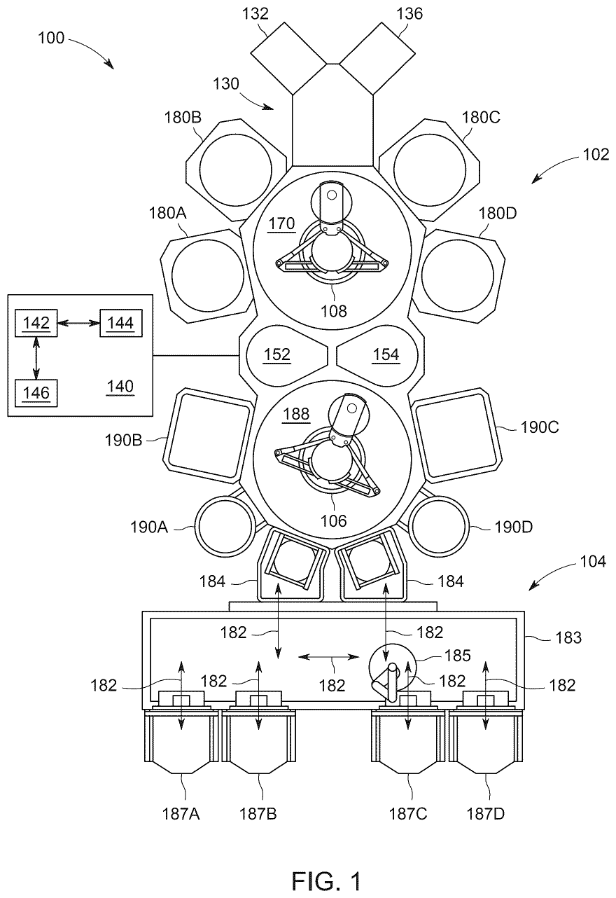

FIG. 1 depicts a schematic top-view of a multi-chamber processing tool in accordance with at least some embodiments of the present disclosure. The inventive batch heating chamber may be a standalone batch heating chamber, or a part of a multi-chamber processing tool. In some embodiments, the multi-chamber processing tool 100 may generally comprise a processing platform 102 that is vacuum-tight, a factory interface 104, and a system controller 140. The processing platform 102 may include at least one load lock chamber 184 (two shown) for transferring substrates into and out of the processing platform 102. A first robot 106 may transfer the substrates between the load lock chambers 184 and a first set of the plurality of process chambers 190A-190D (four are shown) coupled to a first transfer chamber 188.

In some embodiments, the plurality of process chambers 190A-190D comprise one or more batch heating chambers configured to perform degassing or anneal processing. The other process chambers 190A-190D may be configured to perform various functions including layer deposition including atomic layer deposition (ALD), chemical vapor deposition (CVD), physical vapor deposition (PVD), etch, pre-clean, orientation and center-finding, and other substrate processes. Each of the process chambers 190A-190D may include a slit valve or other selectively sealable opening to selectively fluidly couple the respective inner volumes of the process chambers 190A-190D to the inner volume of the first transfer chamber 188. Similarly, each load lock chamber 184 may include a port to selectively fluidly couple the respective inner volumes of the load lock chambers 184 to the inner volume of the first transfer chamber 188. In some embodiments, the batch heating chamber may be the process chamber 190D. In some embodiments, the one or more batch heating chambers may be process chambers 190A and 190D.

The first robot 106 can also transfer substrates to/from two intermediate transfer chambers 152, 154. The intermediate transfer chambers 152, 154 can be used to maintain ultrahigh vacuum conditions while allowing substrates to be transferred within the processing platform 102. A second robot 108 can transfer the substrates between the intermediate transfer chambers 152, 154 and a second set of the plurality of process chambers 180A-180D coupled to a second transfer chamber 170. In some embodiments, the plurality of process chambers 180A-180D comprise one or more batch heating chambers configured to perform degassing or anneal processing. At least one of the plurality of process chambers 180A-180D or 190A-190D comprises a batch heating chamber.

The factory interface 104 is coupled to the first transfer chamber 188 via the load lock chambers 184. In some embodiments, each of the load lock chambers 184 may include a first port coupled to the factory interface 104 and a second port coupled to the first transfer chamber 188. The load lock chambers 184 may be coupled to a pressure control system which pumps down and vents the load lock chambers 184 to facilitate passing the substrate between the vacuum environment of the first transfer chamber 188 and the substantially ambient (e.g., atmospheric) environment of the factory interface 104.

In some embodiments, the factory interface 104 comprises at least one docking station 183 and at least one factory interface robot 185 (one shown) to facilitate transfer of substrates from the factory interface 104 to the processing platform 102 for processing through the load lock chambers 184. The docking station 183 is configured to accept one or more (four shown) front opening unified pods (FOUPs) 187A-D, or load ports. Optionally, one or more metrology stations (not shown) may be coupled to the factory interface 104 to facilitate measurement of the substrate from the FOUPs 187A-D. The factory interface robot 185 disposed in the factory interface 104 is capable of linear and rotational movement (arrows 182) to shuttle cassettes of substrates between the load lock chambers 184 and the one or more FOUPs 187A-D.

The system controller 140 includes a central processing unit (CPU) 142, a memory 144, and support circuits 146. The system controller 140 may control the multi-chamber processing tool 100 directly, or via computers (or controllers) associated with particular process chambers and/or support system components. The system controller 150 may be any form of general purpose computer processor that can be used in an industrial setting for controlling various chambers and sub-processors. The memory, or computer readable medium, 142 of the system controller 140 may be one or more of readily available memory such as random access memory (RAM), read only memory (ROM), floppy disk, hard disk, optical storage media (e.g., compact disc or digital video disc), flash drive, or any other form of digital storage, local or remote. The support circuits 146 are coupled to the CPU 142 for supporting the processor in a conventional manner.

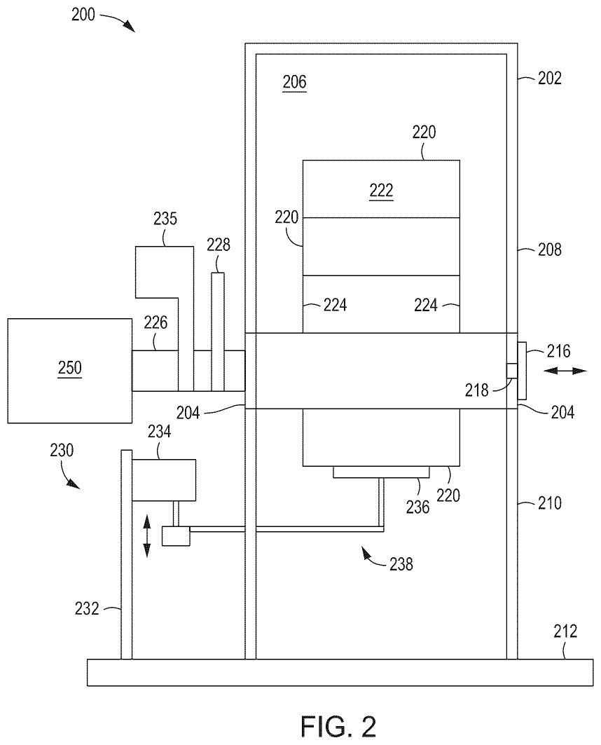

FIG. 2 depicts a schematic side view of a batch heating chamber 200 in accordance with at least some embodiments of the present disclosure. The batch heating chamber 200 may be one of the plurality of process chambers 180A-180D or 190A-190D. The batch heating chamber 200 includes a chamber housing 202 defining an interior volume 206 therein. In some embodiments, the chamber housing 202 includes a central housing 204, a top cover 208 coupled to a top surface of the central housing 204, and a bottom cover 210 coupled to a bottom surface of the central housing 204. In some embodiments, the chamber housing 202 sits atop and is coupled to a base plate 212. The central housing 204 may include a substrate transfer slot 218 disposed adjacent to a substrate slit valve 216 that is configured to selectively exposing the substrate transfer slot 218 for transferring substrates into or out of the interior volume 206.

The batch heating chamber 200 includes a plurality of batch heating cassettes 220 that are vertically stacked within the interior volume 206. The plurality of batch heating cassettes 220 are configured to be raised or lowered in unison within the interior volume 206 (described in more detail below). Each of the plurality of batch heating cassettes 220 comprise a plurality of walls 224 that at least partially define a processing volume 222 therein for processing a plurality of substrates. The plurality of batch heating cassettes 220 generally include openings or the plurality of walls 224 do not form a closed loop so that the plurality of substrates are exposed to the interior volume 206. For example, during a batch heating process for outgassing the plurality of substrates, the plurality of substrates are exposed to the interior volume 206. In some embodiments one or more of the plurality of walls 224, or portions thereof, are made of a mesh structure to advantageously promote ventilation of the processing volume 222.

A pump 250 is coupled to the interior volume 206 via an exhaust line 226 and configured to form a vacuum in the interior volume 206 and exhaust the interior volume 206 (i.e., remove outgassing contaminants). In some embodiments, the pump 250 is a cryopump. In some embodiments, a slit valve 228 is disposed between the chamber housing 202 and the pump 250 to control flow through the exhaust line 226. In some embodiments, the substrate slit valve 216 is disposed on a side of the central housing 204 opposite the exhaust line 226. In some embodiments, a cold trap 235 is advantageously disposed between the chamber housing 202 and the pump 250. In some embodiments, the cold trap 235 is disposed between the slit valve 228 and the pump 250. The cold trap 235 is generally configured to reduce condensation in the exhaust lines 226 by cooling the flow to a temperature where vapors or contaminants can condense and be captured, preventing them from entering downstream components like the pump 250.

In some embodiments, an actuator assembly 230 is coupled to the chamber housing 202 and configured to selectively raise and lower the plurality of batch heating cassettes 220. In some embodiments, a fixed support rod 232 of the actuator assembly 230 is coupled to the base plate 212. In some embodiments, the actuator assembly 230 includes a bracket 234 that is movable up and down with respect to the fixed support rod 232. The bracket 234 is coupled to a support plate 236 disposed below the plurality of batch heating cassettes 220. Accordingly, the plurality of batch heating cassettes 220 may be actuated upwards or downwards via the support plate 236. In some embodiments, the support plate 236 is coupled to the bracket 234 via one or more support arms 238.

In some embodiments, a top plate having one or more heating elements and a bottom plate having one or more heating elements, wherein the plurality of batch heating cassettes comprise five batch heating cassettes, and wherein a lowermost one of the batch heating cassettes provides a first heating zone, an uppermost one of the batch heating cassettes provides a second heating zone, and a middle three of the batch heating cassettes provide a third heating zone, wherein the first heating zone, the second heating zone, and the third heating zone are configured to provide independent heating to the plurality of substrates.

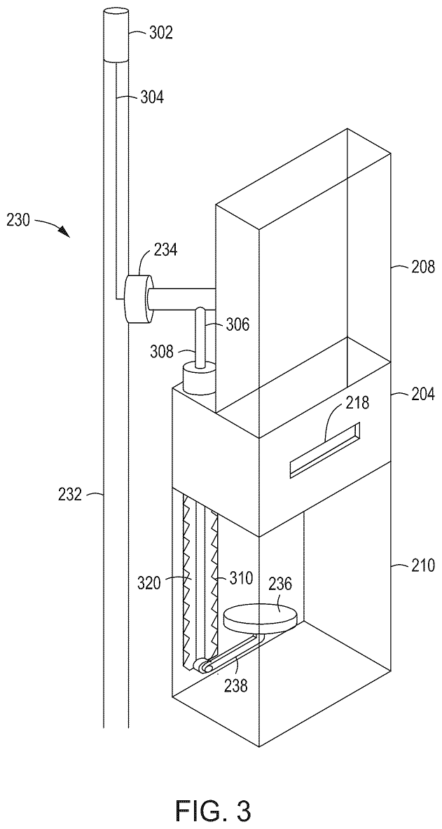

FIG. 3 depicts a schematic isometric view of a batch heating chamber having an actuator assembly 230 in accordance with at least some embodiments of the present disclosure. In FIG. 3, the plurality of batch heating cassettes 220 are not shown to aid in visibility of the actuator assembly 230. In some embodiments, the actuator assembly 230 is a linear actuator assembly. In some embodiments, the actuator assembly 230 includes a motor 302 coupled to the fixed support rod 232. An actuator assembly rod 304 may be coupled to the bracket 234 and is extended or contracted in length by the motor 302 to selectively raise or lower the bracket 234. In some embodiments, an inner shaft assembly 306 is coupled to the bracket 234. The inner shaft assembly 306 includes an inner shaft 308 at least partially disposed in a bellows 310. A lower end of the inner shaft 308 is coupled to the support plate 236 for raising or lowering the plurality of batch heating cassettes 220. FIG. 3 depicts the bellows 310 in an expanded form, where the support plate 236 is at a lower position. When the inner shaft 308 is raised via the bracket 234, the bellows 310 contract. The support plate 236 and a lower portion of the inner shaft 308 are generally disposed in the interior volume 206 within the bottom cover 210. The bellows 310 advantageously provide a seal between the interior volume 206 external to the bellows 310 and an inner volume 320 disposed within the bellows 310.

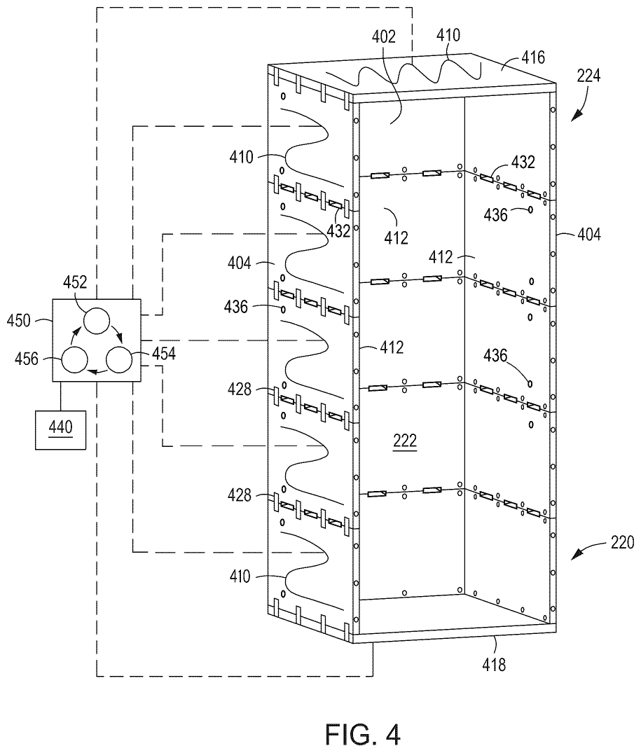

FIG. 4 depicts a schematic isometric view of a plurality of batch heating cassettes 220 that are vertically stacked in accordance with at least some embodiments of the present disclosure. FIG. 4 depicts the plurality of batch heating cassettes without showing the supports for the plurality of substrates in order to aid in visibility of the plurality of walls 224. In some embodiments, the plurality of walls 224 comprise a back wall 402. In some embodiments, the plurality of walls 224 include sidewalls 404 extending from the back wall 402.

In some embodiments, the plurality of batch heating cassettes 220 are coupled together via one or more coupling brackets 428. In some embodiments, upper surfaces of the plurality of walls 224 of one of the plurality of batch heating cassettes 220 are coupled to and abut lower surfaces of the plurality of walls 224 of an adjacent one of the plurality of batch heating cassettes 220, as shown in FIG. 4. In some embodiments, a top plate 416 is coupled to a top one of the plurality of batch heating cassettes 220 and a bottom plate 418 is coupled to a bottom one of the plurality of batch heating cassettes 220. In some embodiments, the plurality of batch heating cassettes 220 comprises five heating cassettes.

One or more heating elements 410 are coupled to one or more of the plurality of walls 224. For example, in some embodiments, the back wall 402 includes one or more heating elements 410 configured to heat the batch heating cassette. In some embodiments, the sidewalls 404 include one or more heating elements 410 configured to heat the batch heating cassette. In some embodiments, the back wall 402 and two of the sidewalls 404 include the one or more heating elements 410 configured to heat the batch heating cassette. The one or more heating elements 410 may comprise resistive heating elements arranged in a suitable shape. In some embodiments, the top plate 416 and the bottom plate 418 each include one or more heating elements 410. The one or more heating elements 410 are not visible in the view of FIG. 4 for the bottom plate 418, the back wall 402, and a distal one (i.e., one on right side) of the sidewalls 404. However, the plurality of heating elements 410 disposed in the bottom plate 418, the back walls 402, and distal sides of the sidewalls 404 are generally similar to as depicted for the top plate 416 and proximal ones (i.e., ones on left side) of the sidewalls 404.

The plurality of heating elements 410 are coupled to a power source 440. In some embodiments, the power source 440 is a single power source configured to power all of the elements of the plurality of heating elements 410. In some embodiments, one or more of the plurality of batch heating cassettes 220 are configured to provide independent heating to the plurality of substrates with respect to each other and with a remainder of the plurality of batch heating cassettes 220. In some embodiments, the power source 440 is a multiple power source configured to provide power independently to the different elements of the plurality of heating elements 410.

The plurality of heating elements 410 may be coupled to a temperature controller 450 to independently control the independent heating to the plurality of batch heating cassettes 220. In some embodiments, each of the plurality of batch heating cassettes 220 can be controlled independently. In some embodiments, the plurality of batch heating cassettes 220 may be arranged into multiple zones. For example, in some embodiments, the heating elements of an uppermost one of the plurality of batch heating cassettes 220 may define a first zone, the heating elements of a lowermost one of the plurality of batch heating cassettes 220 may define a second zone, the heating elements of middle ones of the plurality of batch heating cassettes 220 may define a third zone, the heating elements of the top plate 416 may define a forth zone, and the heating elements of the bottom plate 418 may define a fifth zone. The independent heating control of the plurality of batch heating cassettes advantageously promotes enhanced temperature uniformity within the processing volume 222. For example, the uppermost heating cassette may be warmer because of rising heat from heating of the lower heating cassettes and thus, the heating elements of the uppermost heating cassette may be controlled to be set at a lower temperature as compared to the heating elements of the lowermost heating cassette.

In some embodiments, one or more slots 432 may be disposed between adjacent ones of the plurality of batch heating cassettes 220 to reduce heat transfer therebetween. The reduced heat transfer advantageously promotes independent temperature control of the plurality of batch heating cassettes 220. The or more slots 432 may also advantageously provide or increase gas ventilation, for example, to help remove outgassing materials during processing of substrates. In some embodiments, the one or more slots 432 include a plurality of slots disposed between adjacent sidewalls 404 of the plurality of batch heating cassettes 220. Alternatively, or in combination, in some embodiments, the one or more slots 432 include a plurality of slots disposed between adjacent back walls 402 of the plurality of batch heating cassettes 220. In some embodiments, the one or more coupling brackets 428 comprise a plurality of brackets and the one or more slots 432 are disposed between adjacent ones of the plurality of coupling brackets 428. The one or more slots 432 may comprise any suitable profile such as rectangular, circular, oval, or the like. The one or more slots 432 can be formed by corresponding recesses formed in adjacent ends of respective walls that together define the slots 432. Alternatively, or in combination, in some embodiments, the sidewalls 404 include one or more vent openings 436. In some embodiments, the one or more vent openings 436 include a plurality of vent openings.

The temperature controller 450 generally includes a central processing unit (CPU) 452 comprising one or more processors, a memory 454, and a support circuit 456. The CPU 452 may be any form of a general-purpose computer processor that can be used in an industrial setting. The support circuit 456 is conventionally coupled to the CPU 452 and may comprise a cache, clock circuits, input/output subsystems, power supplies, and the like. Software routines, such as a method as described herein may be stored in the memory 454 and, when executed by the CPU 452, transform the CPU 452 into a specific purpose computer (temperature controller 450). The software routines may also be stored and/or executed by the system controller 140 of the multi-chamber processing tool 100.

The memory 454 may be in the form of a non-transitory computer-readable storage media that contains instructions, when executed by the CPU 452, to facilitate the operation of the one or more batch heating chambers. The instructions in the memory 454 are in the form of a program product such as a program that implements methods of the present principles. The program code may conform to any one of a number of different programming languages. In one example, the disclosure may be implemented as a program product stored on a computer-readable storage media for use with a computer system. The program(s) of the program product define functions of the aspects (including the methods described herein). Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of the methods described herein, are aspects of the present principles.

In some embodiments, substrate facing surfaces 412 of the plurality of walls 224, for example, inner surfaces of the back wall 402 and the sidewalls 404, are anodized to increase emissivity of the substrate facing surfaces. The increased emissivity advantageously promotes radiation of heat from the plurality of walls 224 to the plurality of substrates when disposed in the processing volume 222.

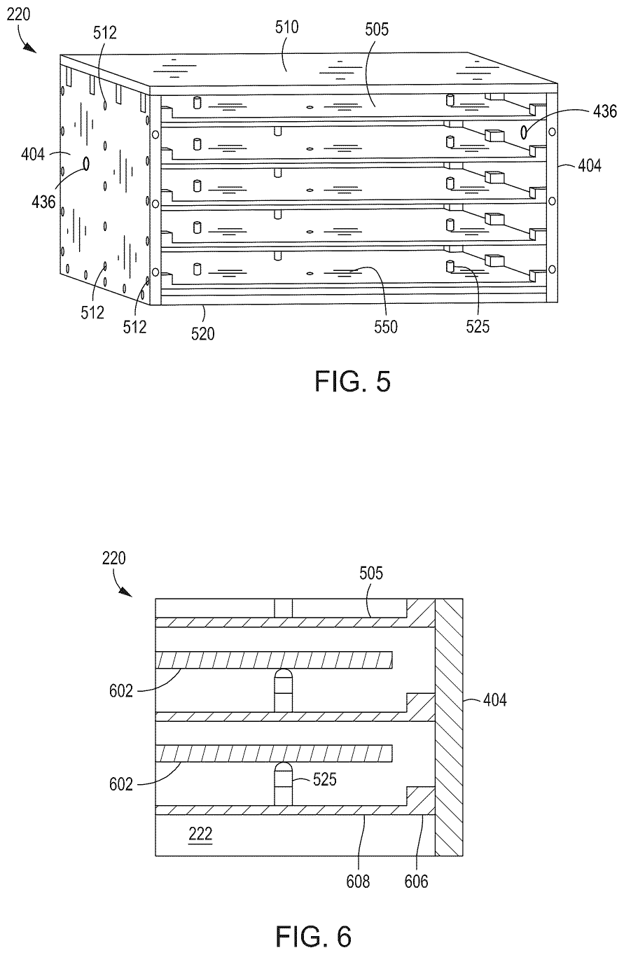

FIG. 5 depicts an isometric view of a batch heating cassette 220 in accordance with at least some embodiments of the present disclosure. In some embodiments, a heating cassette of the plurality of batch heating cassettes 220 includes an upper plate 510 coupled to upper surfaces of the plurality of walls 224 and a lower plate 520 coupled to bottom surfaces of the plurality of walls 224. In some embodiments, the upper plate 510 of the heating cassette is coupled to the lower plate 520 of an adjacent heating cassette. In some embodiments, the upper plate 510 of an uppermost one of the plurality of batch heating cassettes 220 is the top plate 416. In some embodiments, the lower plate 520 of a lowermost one of the plurality of batch heating cassettes 220 is the bottom plate 418.

In some embodiments, a plurality of support plates 505 are coupled to at least one of the plurality of walls 224. In some embodiments, the plurality of support plates 505 are coupled to the sidewalls 404. The plurality of support plates 505 are configured to horizontally support a plurality of substrates in a vertically stacked and spaced arrangement (see substrates in FIG. 6). A plurality of support pins 525 are disposed on each of the plurality of support plates 505 and configured to elevate the plurality of substrates above respective ones of the plurality of support plates 505. Elevating the plurality of substrates advantageously exposed the lower surfaces of the substrates for more uniform heating and facilitating outgassing of the surface surfaces of the substrates. In some embodiments, the plurality of support pins 525 comprise three pins disposed at regular intervals along a common circular path. In some embodiments, each of the plurality of support plates 505 have one or more openings 550 therethrough to promote venting of outgassing material.

In some embodiments, the sidewalls 404 have a plurality of openings 512 and the plurality of support plates 505 are secured to the sidewalls 404 via, for example, fasteners extending through the plurality of openings 512. In some embodiments, the batch heating chamber 200 is configured to support about 20 to about 30 substrates. In some embodiments, each of the plurality of batch heating cassettes 220 include 4 to 6 support plates of the plurality of support plates 505.

FIG. 6 depicts a cross-sectional side view of a portion of a batch heating cassette 220 in accordance with at least some embodiments of the present disclosure. In some embodiments, the plurality of support plates 505 are spaced about 20 to about 40 mm apart. A plurality of substrates 602 are disposed atop respective ones of the plurality of support pins 525. In some embodiments, the plurality of support plates 505 have an outer rim 606 that is thicker than a central portion 608 of the support plates 505.

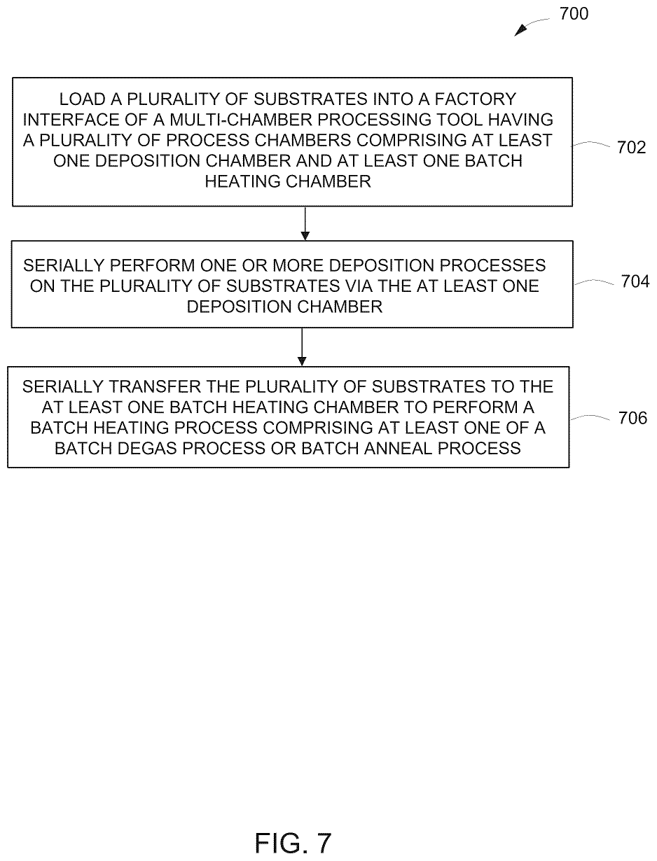

FIG. 7 depicts a flow chart of a method 700 of processing a substrate in accordance with at least some embodiments of the present disclosure. At 702, the method 700 includes loading a plurality of substrates into a factory interface of a multi-chamber processing tool having a plurality of process chambers comprising at least one deposition chamber and at least one batch heating chamber. In some embodiments, the plurality of substrates are loaded into the batch heating chamber on a first-on-first-off basis.

At 704, the method 700 includes serially performing one or more deposition processes on the plurality of substrates via the at least one deposition chamber. The one or more deposition processes may comprise any suitable process such as a physical vapor deposition process, a chemical vapor deposition process, an epitaxial growth process, an atomic layer deposition process, or the like. In some embodiments, the one or more deposition processes may be followed by one or more etch processes.

At 706, the method 700 includes serially transferring the plurality of substrates to the at least one batch heating chamber to perform a batch heating process comprising at least one of a batch degas process or batch anneal process. In some embodiments, the batch heating process is a batch anneal process. For example, the batch anneal process may follow deposition of an indium tin oxide (ITO) film on the plurality of substrates. The at least one batch heating chamber comprises a plurality of batch heating cassettes that are vertically stacked.

ITO film deposition typically requires a post deposition anneal process to improve electrical conductivity and transmittance of the ITO film. ITO films often have a relatively high resistance when initially deposited. Annealing helps to reduce the resistivity by promoting the rearrangement of the atoms in the film, allowing for more efficient electron flow, leading to better conductivity, for example, for use in applications in touchscreens, displays, and solar cells. ITO films are typically used for their transparent conductive properties, so improving the optical clarity of the ITO film is advantageous. Annealing can help to reduce the scattering of light, which improves the transparency of the film. The process can also remove defects or non-uniformities in the film, contributing to better light transmission. In some embodiments, the batch appeal process may be performed for about 10 to about 20 minutes. In some embodiments, the plurality of substrates 602 for annealing may comprise glass substrates.

In some embodiments, the plurality of substrates are complex packaging wafers such as chip-on-wafer (CoW) substrates and the batch heating process is a batch degas process. Heating is typically used for outgassing CoW substrates to remove volatile substances and residual gases that may be trapped within the materials used during the fabrication process as various materials, such as adhesives, fluxes, and coatings, may be applied to the wafer or chip. Such materials often contain volatile compounds or moisture that can become trapped inside the substrate or at interfaces. Heating helps to release (or “outgas”) these compounds, preventing interference with the functionality of the device. Any trapped volatile substances can also affect the strength and quality of the bond. Outgassing via heating may ensure that there is little to no residual contamination or moisture that could weaken the bond or lead to premature device failure. In some embodiments, the batch degas process may be performed for about 30 minutes to 90 minutes.

While the foregoing is directed to embodiments of the present disclosure, other and further embodiments of the disclosure may be devised without departing from the basic scope thereof.

1. A batch heating chamber, comprising:
a plurality of batch heating cassettes that are vertically stacked, wherein each batch heating cassette comprises:
a plurality of walls partially defining a processing volume;
one or more heating elements coupled to one or more of the plurality of walls;
a plurality of support plates coupled to at least one of the plurality of walls, wherein the plurality of support plates are configured to horizontally support a plurality of substrates in a vertically stacked and spaced arrangement; and
a plurality of support pins disposed on each of the plurality of support plates, wherein the support pins are configured to elevate the plurality of substrates above respective ones of the plurality of support plates.

2. The batch heating chamber of claim 1, wherein the plurality of walls comprise:
a back wall; and
sidewalls extending from the back wall and each sidewall having the one or more heating elements configured to heat the processing volume of each batch heating cassette.

3. The batch heating chamber of claim 2, wherein the sidewalls have a plurality of openings and the plurality of support plates are secured to the sidewalls via the plurality of openings.

4. The batch heating chamber of claim 1, wherein substrate facing surfaces of the plurality of walls are anodized.

5. The batch heating chamber of claim 1, further comprising:
a top plate coupled to a top one of the plurality of batch heating cassettes and a bottom plate coupled to a bottom one of the plurality of batch heating cassettes, wherein the top plate and the bottom plate each include one or more heating elements.

6. The batch heating chamber of claim 1, wherein one or more of the plurality of batch heating cassettes are configured to be independently controlled with respect to each other and with a remainder of the plurality of batch heating cassettes.

7. The batch heating chamber of claim 1, wherein a heating cassette of the plurality of batch heating cassettes includes an upper plate coupled to upper surfaces of the plurality of walls and a lower plate coupled to bottom surfaces of the plurality of walls, wherein the upper plate of the heating cassette is coupled to the lower plate of an adjacent heating cassette.

8. The batch heating chamber of claim 1, wherein upper surfaces of the plurality of walls of one of the plurality of batch heating cassettes are coupled to and abut lower surfaces of the plurality of walls of an adjacent one of the plurality of batch heating cassettes.

9. The batch heating chamber of claim 1, wherein at least one of:
each of the plurality of batch heating cassettes include 4 to 6 support plates of the plurality of support plates; or
the plurality of support plates are spaced about 20 to about 40 mm apart.

10. A batch heating chamber, comprising:
a chamber housing defining an interior volume therein;
a plurality of batch heating cassettes that are vertically stacked within the interior volume, wherein each batch heating cassette comprises:
a back wall having one or more heating elements configured to heat the batch heating cassette;
sidewalls extending from the back wall having one or more heating elements configured to heat the batch heating cassette;
a plurality of support plates coupled to the sidewalls, wherein the support plates are configured to hold a plurality of substrates in a vertically stacked arrangement; and
a plurality of support pins disposed on each of the plurality of support plates, wherein the support pins are configured to elevate the plurality of substrates above respective ones of the plurality of support plates; and
a pump port configured to be coupled to a pump.

11. The batch heating chamber of claim 10, wherein the plurality of support plates are anodized, and wherein interior surfaces of the back wall and the sidewalls are anodized.

12. The batch heating chamber of claim 10, further comprising a cold trap disposed between the chamber housing and the pump.

13. The batch heating chamber of claim 10, further comprising an actuator assembly coupled to the chamber housing and configured to selectively raise and lower the plurality of batch heating cassettes.

14. The batch heating chamber of claim 10, wherein the chamber housing includes a substrate transfer slot.

15. The batch heating chamber of claim 10, further comprising a top plate having one or more heating elements and a bottom plate having one or more heating elements, wherein the plurality of batch heating cassettes comprise five batch heating cassettes, and wherein a lowermost one of the batch heating cassettes provides a first heating zone, an uppermost one of the batch heating cassettes provides a second heating zone, and a middle three of the batch heating cassettes provide a third heating zone, wherein the first heating zone, the second heating zone, and the third heating zone are configured to be independently controlled.

16. A multi-chamber processing tool, comprising:
a factory interface having one or more load ports for receiving a substrate;
a transfer chamber coupled to the factory interface, the transfer chamber having a robot; and
a plurality of process chambers coupled to the transfer chamber, wherein at least one of the plurality of process chambers includes the batch heating chamber of claim 10.

17. A method of processing a substrate, comprising:
loading a plurality of substrates into a factory interface of a multi-chamber processing tool having a plurality of process chambers comprising at least one deposition chamber and at least one batch heating chamber;
serially performing one or more deposition processes on the plurality of substrates via the at least one deposition chamber; and
serially transferring the plurality of substrates to the at least one batch heating chamber to perform a batch heating process comprising at least one of a batch degas process or batch anneal process, wherein the at least one batch heating chamber comprises a plurality of batch heating cassettes that are vertically stacked.

18. The method of claim 17, wherein the batch heating process is a batch anneal process following deposition of an indium tin oxide film on the plurality of substrates.

19. The method of claim 17, wherein the plurality of substrates are chip-on-wafer substrates and the batch heating process is a batch degas process.

20. The method of claim 17, wherein the plurality of substrates are loaded into the batch heating chamber on a first-on-first-off basis.
